(19) United States
(12) Patent Application Publication
(10) Pub. No.: US 2013/0074919 A1
(43) Pub. Date: Mar. 28, 2013

(54) ACTUATABLE PUNCH ASSEMBLY, METHOD OF USING SAME, AND A LAMINATE PREPARED THEREBY

(71) Applicant: Dow Coming Corporation, Midland, MI (US)

(72) Inventor: Robert Leo Oldinski, Bay City, MI (US)

(73) Assignee: DOW CORNING CORPORATION, Midland, MI (US)

(21) Appl. No.: 13/624,245

(22) Filed: Sep. 21, 2012

Related U.S. Application Data
(60) Provisional application No. 61/538,256, filed on Sep. 23, 2011.

(51) Int. Cl. B26D 7/26; B26D 3/14; H01L 31/18; H01L 31/0203

(52) U.S. Cl. 136/256; 83/699.31; 83/30; 438/67; 257/E31.113

(57) ABSTRACT

An actuatable punch assembly forms a hole within an article. The actuatable punch assembly comprises a base plate coupled to the actuator. At least one segment block is adjustably coupled to the base plate. At least one cutting device for forming the hole within the article is coupled to the segment block. The segment block is adjustable relative to the base plate. The cutting device is adjustable relative to the segment block. As such, the cutting device is adjustable relative to the base plate for varying a position of the cutting device relative to the article to vary a size of the hole formed in the article.

### CROSS-REFERENCE TO RELATED APPLICATIONS

This application claims priority to and all advantages of U.S. Provisional Patent Application Ser. No. 61/538,256, which was filed on Sep. 23, 2011, the entire specification of which is expressly incorporated herein by reference.

### FIELD OF THE INVENTION

The present invention generally relates to an actuatable punch assembly.

### BACKGROUND OF THE INVENTION

Conventional actuatable punch assemblies are used in manufacturing processes to produce a hole in an article made from, for example, plastics and textiles. Generally, the actuatable punch assembly includes an actuator operatable between a contact and spaced position. The actuator may have a head with cutting devices disposed thereon for forming a hole in an article. The cutting devices on the head are arranged in a set pattern, which corresponds to a certain size and/or shape of the hole. When a hole of a different size and/or shape is desired, then the head has to be completely removed and the replaced with a different head having the cutting devices arranged in a different pattern. The required replacement of the head results in a significant amount of down time to allow for proper change out of the head every time the hole of a different and/or shape is desired. Therefore, the use of conventional actuatable punch assemblies limits the ability to vary the size and/or location of the hole to be formed in the article. Therefore, at great cost, multiple heads having cutting devices in various patterns must be purchased and employed with each of the heads set up to meet the requirements of a specific end user.

### SUMMARY OF THE INVENTION AND ADVANTAGES

This invention provides an actuatable punch assembly for forming a hole within an article. The actuatable punch assembly comprises an actuator operational between a cutting position and a spaced position. The actuatable punch assembly also comprises a base plate coupled to the actuator. At least one segment block is adjustably coupled to the base plate with at least one cutting device coupled to the segment block. The cutting device is coupled to the segment block for forming the hole within the article. In operation, each of the base plate, the segment block, and the cutting device move with the actuator between the cutting position and the spaced position. The cutting device pierces the article for forming the hole within the article in the cutting position. Alternatively, the cutting device is spaced apart from the article in the spaced position.

The segment block is adjustable relative to the base plate. The cutting device is coupled to the segment block and is also adjustable relative to the base plate. The cutting device is adjustable relative to the base plate for varying a position of the cutting device relative to the article to vary a size/shape of the hole formed in the article.

This invention also provides a method of using the actuatable punch assembly.

### BRIEF DESCRIPTION OF THE DRAWINGS

Other aspects of the present invention may be understood by reference to the following detailed description and the accompanying drawings wherein:

FIG. 1 is a perspective view of an actuatable punch assembly for forming a hole in an article;

FIG. 2 is a side view of the actuatable punch assembly with a portion of a housing cut away to reveal an actuator, a base plate, a segment block, and a cutting device in a spaced position;

FIG. 3 is a side view of the actuatable punch assembly with a portion of a housing cut away to reveal an actuator, a base plate, a segment block, and a cutting device in a cutting position;

FIG. 4 is a top view of the base plate showing a plurality of cavities uniformly spaced in rows and columns along a coupling surface of the base plate;

FIG. 5 is a top view of an alternative embodiment of the base plate having a plurality of slots spaced along the coupling surface of the base plate;

FIG. 6 is a perspective view of the segment block;

FIG. 7 is a perspective view of an alternative embodiment of the segment block;

FIG. 8 is a perspective view of the base plate with the segment block coupled to the base plate;

FIG. 9 is an assembly view of the base plate with the segment block spaced from the base plate;

FIG. 10 is a top view of the article defining two holes formed by the actuatable punch assembly;

FIG. 11 is a top view is a top view of an alternative embodiment of the article having multiple flaps spaced from one another formed by the actuatable punch assembly.

FIG. 12 is a top view of an alternative embodiment of the article having a flap formed by the actuatable punch assembly;

FIG. 13 is a top view of 12 an alternative embodiment of the article having a flap formed by the actuatable punch assembly;

FIG. 14 is a schematic top view of a solar cell laminate;

FIG. 15 is a cross-sectional view of the solar cell laminate taken along line 15-15 of FIG. 14 with the solar cell laminate having a backing layer defining a hole formed by the actuatable punch assembly;

FIG. 16 is a cross-section view of the solar cell laminate taken along line 15-15 of FIG. 14 with a junction box coupled to the solar cell laminate;

FIG. 17 is a cross-sectional view of an alternative embodiment of the solar cell laminate showing the backing layer defining a flap formed by the actuatable punch assembly; and

FIG. 18 is an automated assembly line for manufacturing the solar cell laminate.

### DETAILED DESCRIPTION OF THE INVENTION

Referring to the Figures, wherein like numerals indicate like or corresponding parts throughout the several views, an actuatable punch assembly is generally shown at 20. Generally, the actuatable punch assembly 20 is used to form at least one hole 22 within an article 24. The article may comprise any material, such as metal, plastic, or textile.

In one embodiment of the invention, the article 24 is a backing layer 26 of a solar cell laminate 28. The actuatable punch assembly 20 may be incorporated into an assembly line or may be a stand-alone device. Furthermore, the actuatable punch assembly 20 may be manually operated or automatically operated.

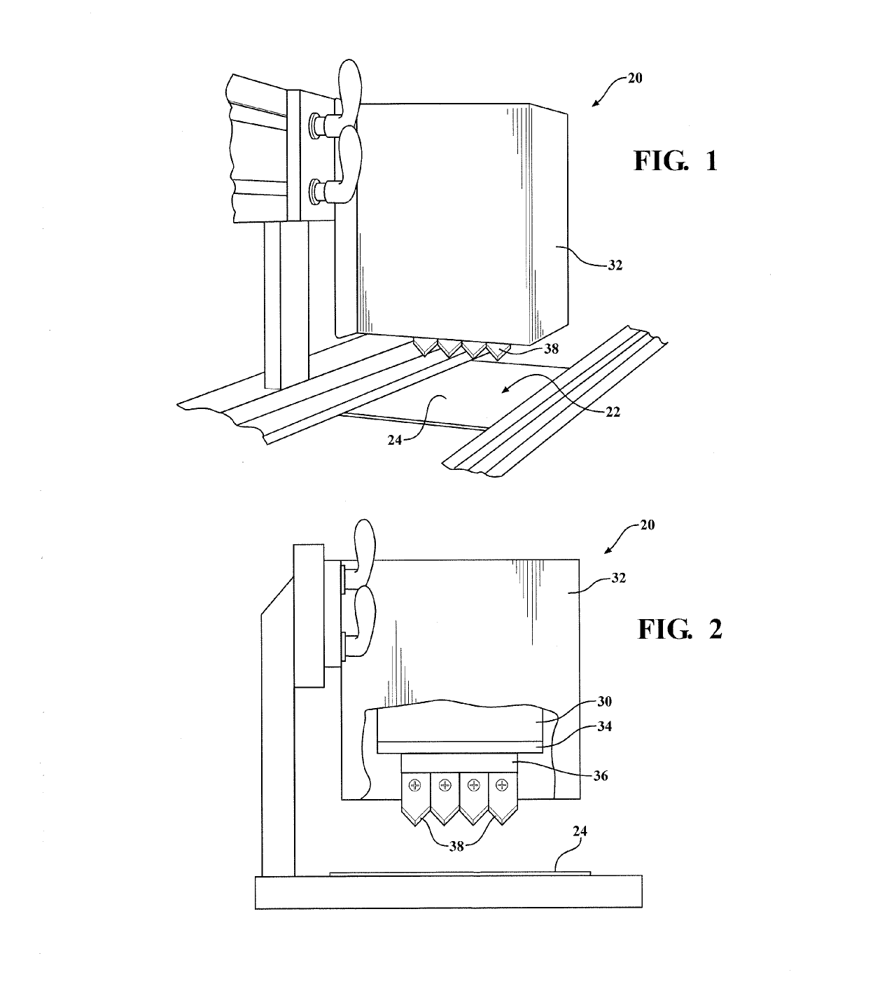

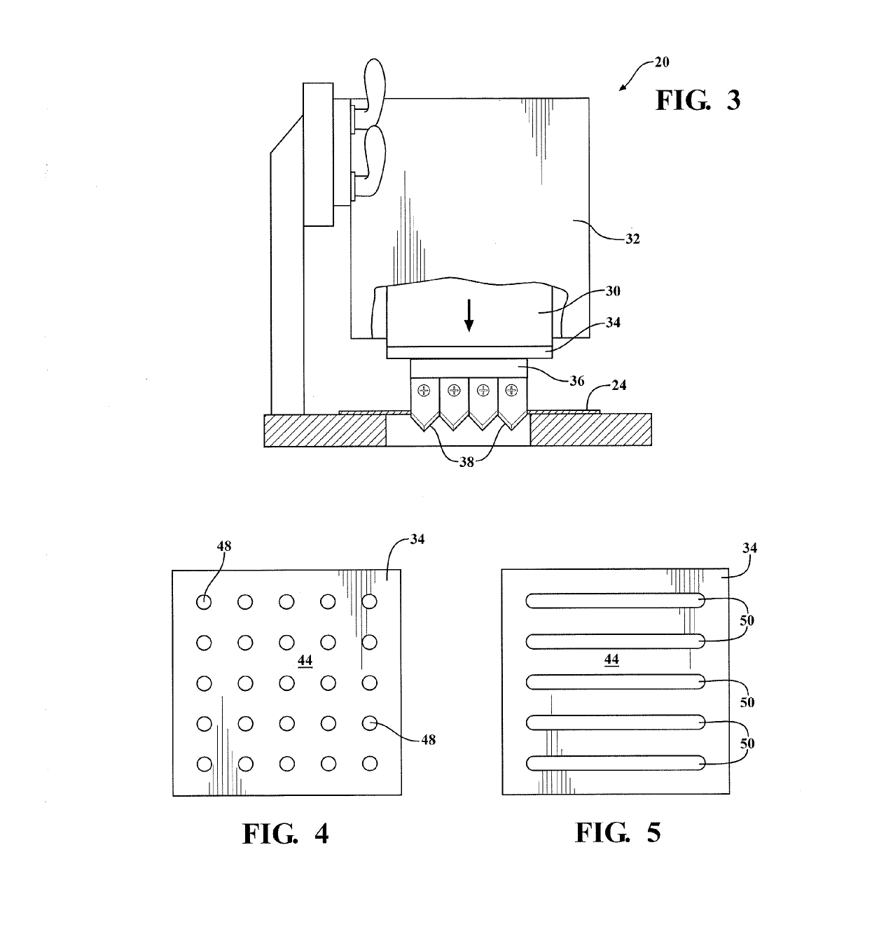

The actuatable punch assembly 20 includes an actuator 30 operational between a spaced position, as shown in FIGS. 1 and 2, and a cutting position, as shown in FIG. 3. However, the actuator 30 may remain stationary and the article 24 may move between the spaced position and the cutting position. Both the actuator 30 and the article 24 may move relative to each other between the spaced position and the cutting position. Generally, the actuator 30 is disposed within a housing 32 when the actuator 30 is in the spaced position and extends from the housing 32 when the actuator 30 is in the cutting position. However, the housing 32 may be coupled to the actuator 30 such that the housing 32 moves with the actuator 30 as the actuator 30 moves between the spaced position and the cutting position. Furthermore, the actuator 30 may not be completely disposed within the housing 32 when in the actuator 30 is in the spaced position.

Referring to FIGS. 2 and 3, the actuatable punch assembly 20 includes a base plate 34 coupled to the actuator 30. At least one segment block 36 is adjustably coupled to the base plate 34. The segment block 36 includes at least one cutting device 38 for forming the hole 22 within the article 24. Typically, the cutting device 38 is adjustably coupled to the segment block 36. A cutting device fastener 40, such as a screw, may be used to couple the cutting device 38 to the segment block 36. The cutting device 38 may be integral with the segment block 36 such that the cutting device 38 is not adjustable relative to the segment block 36.

The base plate 34, the segment block 36, and the cutting device 38 move with the actuator 30 between the cutting position and the spaced position. The cutting device 38 is coupled to the base plate 34 via the segment block 36 and therefore the cutting device 38 and the segment block 36 move with the base plate 34 as the actuator 30 moves between the spaced position and the cutting position.

As shown in FIG. 2, the cutting device 38 is spaced from the article 24 when the actuator 30 is in the spaced position. Alternatively, as shown in FIG. 3, the cutting device 38 pierces the article 24 for forming the hole 22 within the article 24 when the actuator 30 is in the cutting position. Said differently, the article 24 is stamped with the cutting device 38 for forming the hole 22 within the article 24. The cutting device 38 may pierce the article 24 completely about a perimeter of the hole 22 such that a portion of the article 24 is completely removed from the article 24. Alternatively, the cutting device 38 may only pierce a portion of the perimeter of the hole 22 formed in the article 24 such that a flap 42 remains coupled to the article 24.

The coupling of the cutting device 38 to the segment block 36 and the coupling of the segment block 36 to the base plate 34 results in the cutting device 38 presenting a pattern. The pattern may have any shape. The pattern of the cutting device 38 depends on a size and/or shape of the hole 22 to be formed in the article 24. Said differently, the hole 22 formed in the article 24 takes a similar configuration to the pattern of the cutting device 38. For example, if the cutting device 38 has a rectangular pattern, then the hole 22 formed in the article 24 by the actuatable punch assembly 20 will have a rectangular configuration, as shown in FIGS. 10-13. Likewise, if the cutting device 38 has a triangular pattern, then the hole 22 formed in the article 24 by the actuatable punch assembly 20 will have a triangular configuration, as shown in FIG. 11. Alternatively, the pattern of the cutting device 38 may be pentagonal, circular, oval, zigzagged, or irregular. The actuatable punch assembly 20 may include multiple cutting devices 38 with the cutting devices 38 orientated in an intersecting relationship relative to each other for forming the flap 42 in the article 24. Alternatively, the cutting device 38 may have a bend to form two intersecting segments for forming the flap 42 in the article 24.

The size and/or shape of the hole 22 to be formed in the article 24 depends on an end user's intended application of the article 24. Different end users may desire (e.g., require) different sizes and/or shapes for the hole 22 to be formed in the article 24. As such, the segment block 36 and the cutting device 38 are adjustable relative to the base plate 34 for adjusting the pattern presented by the cutting device 38 relative to the article 24. Allowing the pattern presented by the cutting device 38 coupled to the segment block 36 to be varied allows the actuatable punch assembly 20 to form the hole 22 with different sizes and/or shapes to accommodate different end users without having to completely change to a non-adjustable base plate, which has cutting devices having a set non-adjustable pattern. Said differently, the pattern of the cutting device 38 is adjustable depending on the size and/or shape desired by the end user.

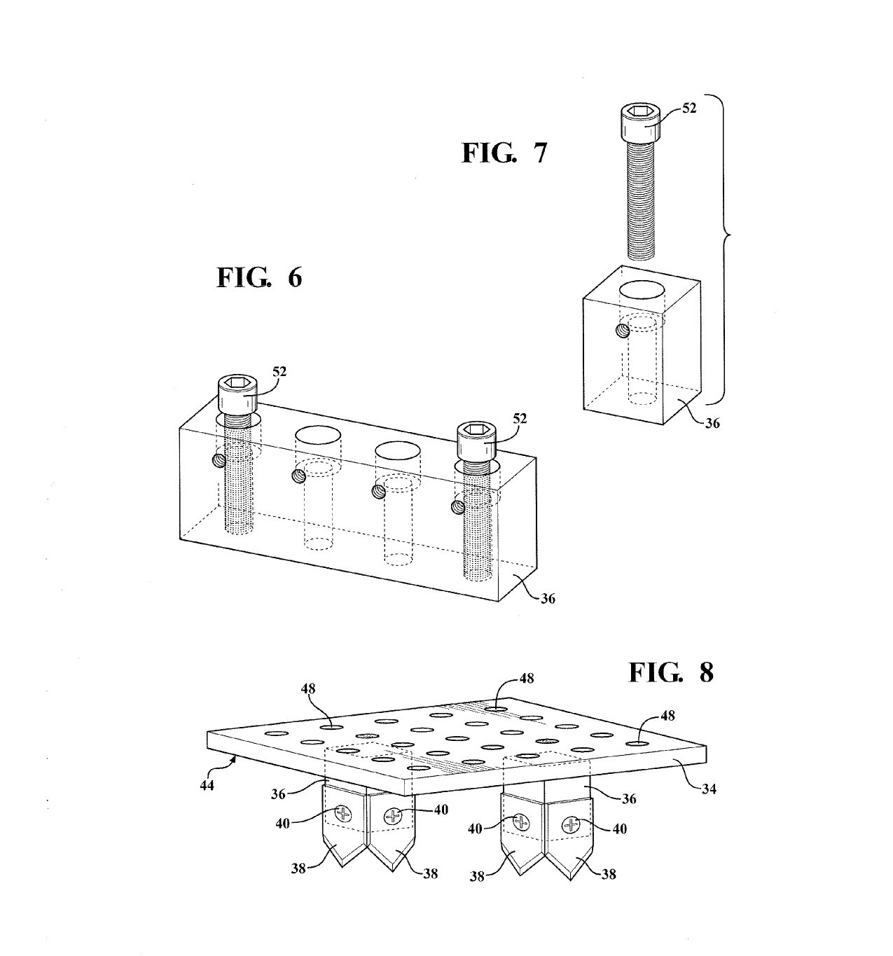

The pattern of the cutting device 38 can be varied in other ways besides adjusting either the segment block 36 or the cutting device 38. For example, the base plate 34 may include multiple segment blocks 36 and that each segment block 36 may include multiple cutting devices 38, as shown in FIG. 8. The number of cutting devices 38 and/or segment blocks 36 required depends on the pattern the cutting devices 38 are to present. For example, two segment blocks 36 may be coupled to the base plate 34 in a spaced relationship with each of the segment blocks 36 having the cutting device 38 for forming two different holes 22 in the article 24, as shown in FIG. 8. Alternatively, the two segment blocks 36 may be coupled next to each other for with the cutting device 38 of each of the segment blocks 36 cooperating to increase the pattern of the cutting device 38 to the size and/or shape of the hole 22 that is not possible to create from a single segment block 36. For example, when the size of the hole 22 is larger than a length of the segment block 36, multiple segment blocks 36 can be used to obtain the size of the hole 22. When multiple segment blocks 36 are used, each of the segment blocks 36 may have different dimensions for accommodating different sizes of the hole 22. For example, with reference to FIGS. 6 and 7, some of the segment blocks 36 may have a first length L1 and other segment blocks 36 may have a second length L2 that is shorter than the first length L1.

The location of the hole 22 relative to the article 24 can be varied by adjusting the segment block 36. For example, if a position of the article 24 relative to the base plate 34 remains constant, adjusting the segment block 36, which has the cutting device 38 coupled thereto, can result in the location of the hole 22 to be formed in the article 24 to be moved to a different location. This is beneficial in continuous manufacturing processes where the pattern of the cutting device 38 can be varied quickly and easily for producing multiple articles 24 having the hole 22 in different locations depending on a particular end user's desired size and/or shape.

Referring to FIGS. 4 and 5, typically, the base plate 34 has a general rectangular configuration. The base plate 34 may have other configurations, such as triangular. The base plate 34 has a coupling surface 44 for receiving the segment block 36. Typically, the base plate 34 defines at least one cavity. More typically, the base plate 34 defines a plurality of cavities. The cavities may have any shape. For example, the plurality of cavities may be further defined as a plurality of receiving holes 48, as shown in FIG. 4. Alternatively, the plurality of cavities may be further defined as a plurality of slots 50, as shown in FIG. 5. The cavities may be uniformly spaced along the coupling surface 44 of the base plate 34 or the cavities may be irregularly spaced along the coupling surface 44 of the base plate 34. The cavities may be uniformly spaced in a plurality of rows and a plurality of columns along the coupling surface 44 of the base plate 34.

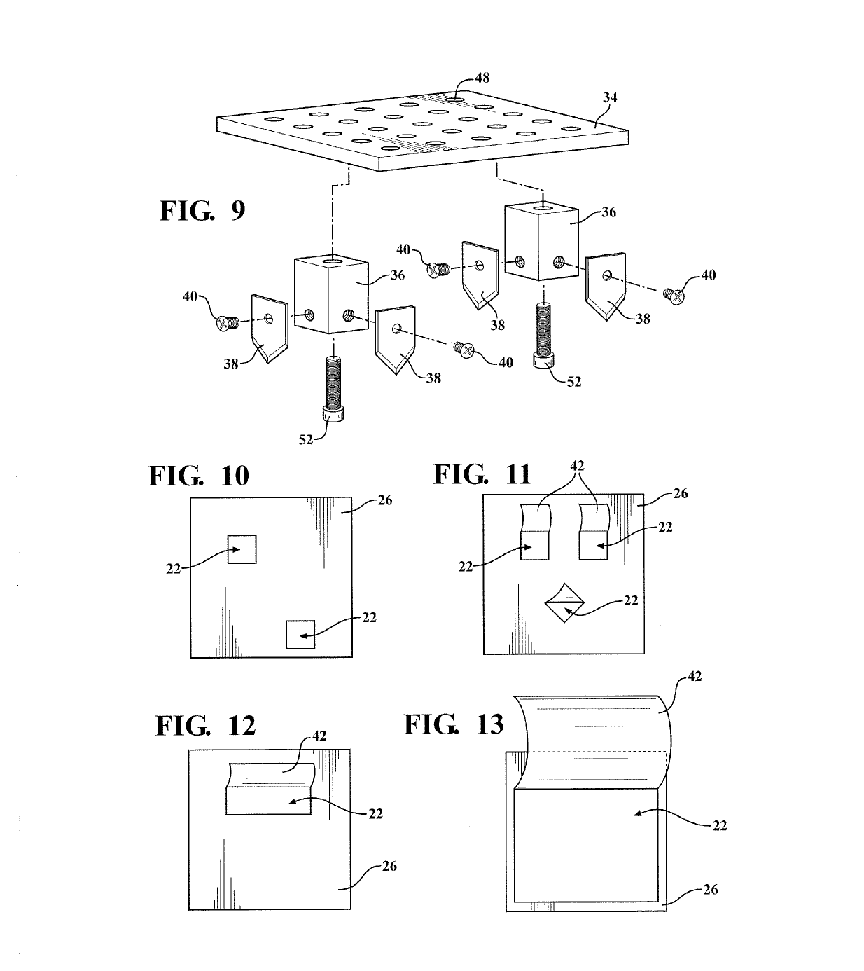

Referring to FIGS. 6-9, the segment block 36 is coupled to the base plate 34 at one of the cavities. A segment fastener 52 may be disposed though the segment block 36 for engaging the portion of the base plate 34 defining the cavities. In such an embodiment, the segment fastener 52 and the cavities may be threaded for coupling the segment fastener 52, and therefore the segment block 36, to the base plate 34 via the threads in the cavities. The use of the plurality of cavities, as either the receiving holes 48 or the slots 50, allows a position of the segment block 36 relative to the base plate 34 to be adjusted. Said differently, the segment block 36 is adjustable relative to the base plate 34. With respect to the slots 50, the segment block 36 is adjusted relative to the base plate 34 by loosening the segment fastener 52 and sliding the segment block 36 to a different location. The segment fastener 52 may have tabs on an end for engaging the slots 50 to allow the segment block 36 to be slid along the slots 50. For example, the segment fastener 52 may have a trapped car configuration such that a T-shaped portion of the segment fastener 52 is inserted into one of the slots 50 with the T-shaped portion slidable along the slots 50. The cutting device 38 is adjustable relative to the segment block 36 for varying a position of the cutting device 38 relative to the segment block 36 and therefore relative to the base plate 34. Generally, the adjustment of the segment block 36 relative to the base plate 34 is used to make larger adjustments to the size of the hole 22 to be formed in the article 24 and the adjustment of the cutting device 38 relative to the segment block 36 is used to make smaller adjustments to the size of the hole 22 to be formed in the article 24.

The actuatable punch assembly 20 may include an automated cutting device adjuster, such as a robotic arm, for adjusting the position of the cutting device 38 relative to the segment block 36 to adjust the pattern presented by the cutting device 38. The automated cutting device adjuster can adjust the position of the segment block 36 relative to the base plate 34 to adjust the position of the cutting device 38 relative to the article 24.

A method of forming the hole 22 within the article 24 using the actuatable punch assembly 20 is described below. The method includes the step of positioning the article 24 relative to the actuatable punch assembly 20. The article 24 can be positioned relative to the actuatable punch assembly 20 such that the location on the article 24 where the hole 22 is to be formed can be changed by moving the article 24. Alternatively, the actuatable punch assembly 20 can be moved relative to the article 24 for changing the location on the article 24 where the hole 22 is to be formed.

The method also includes the steps of selecting the size of the hole 22 to be formed within the article 24 and adjusting the cutting device 38 in accordance with the size selected for the hole 22 to be formed within the article 24. When there is more than one cutting device 38 present, the step of adjusting the cutting device 38 may be further defined as adjusting at least one of the cutting devices 38. The step of adjusting the cutting device 38 may be further defined as adjusting the position of the cutting device 38 relative to the segment block 36 and/or adjusting the position of the segment block 36 relative to the base plate 34 based on the size of the hole 22 to be formed in the article 24. The step of forming the hole 22 in the article 24 may be further defined as piercing the article 24 to form the foldable flap 42 in the article 24. As such, the method may include the step of folding the flap 42 back upon the article 24 to gain access to the hole 22.

The method further includes the step of forming the hole 22 in the article 24 by moving the actuatable punch assembly 20 from the spaced position to the cutting position such that the cutting device 38 pierces the article 24. The method may include the step of identifying a location to form the hole 22 in the article 24. As such, the method may include the step of adjusting the segment block 36 relative to the base plate 34 based on the location identified to form the hole 22 in the article 24.

When the actuatable punch assembly 20 includes the automated cutting device adjuster, the method may include the step of selecting the size of the hole 22 to be formed in the article 24 may be further defined as entering an article 24 identifier into the automated cutting device adjuster to automatically adjust the position of the cutting device 38 relative to the segment block 36 and/or to automatically adjust the position of the segment block 36 relative to the base plate 34 based on the article 24 identifier.

The use of the actuatable punch assembly 20 may be incorporated into an automated process. In such an embodiment, the article 24 may be further defined as a first article 24 and a second article 24. Generally, the hole 22 is formed in the first article 24 and the hole 22 in the second article 24 is subsequently formed. Therefore, the method of forming the hole 22 in the first and second article 24s would include the steps of positioning the second article 24 relative to the actuatable punch assembly 20, selecting the size of the hole 22 to be formed in the second article 24, adjusting the cutting device 38 in accordance with the size of the hole 22 to be formed in the second article 24, and forming the second hole 22 in the second article 24 by moving the actuatable punch assembly 20 from the spaced position to the cutting position such that the cutting device 38 pierces the second article 24.

The size of the hole 22 to be formed in the second article 24 may be different than the size of the hole 22 to be formed in the first article 24. For example, different end users may desire different sizes, or even different locations, for the hole 22s in the article 24. In such an embodiment, a second article 24 identifier is entered into the automated cutting device adjuster to automatically adjust the position of the cutting device 38 relative to the segment block 36 and/or to automatically adjust the position of the segment block 36 relative to the base plate 34 based on the second article 24 identifier.

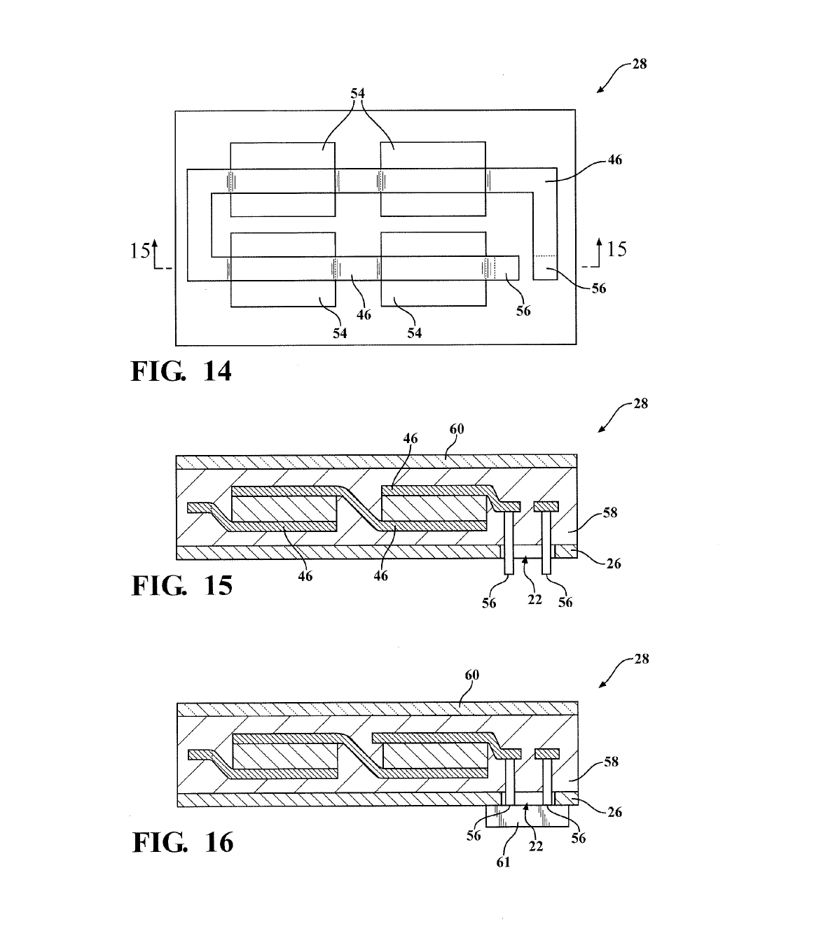

Referring to FIG. 14 and as indicated above, the article 24 may be the backing layer 26 of the solar cell laminate 28. Generally, the solar cell laminate 28 comprises a solar cell matrix 54 interconnected by a ribbon 46. The solar cell laminate 28 shown in FIG. 14 is only a schematic of a four-cell solar cell laminate. The solar cell matrix 54 of the solar cell laminate 28 may include any number of cells.

The solar cell matrix 54 has at least one lead 56. More typically, the solar cell matrix 54 has a pair of leads 56 coupled to and extending from the solar cell matrix 54. The leads 56 are coupled to the ribbon 46. The solar cell laminate 28 also has a gel layer 58, typically comprising silicone, encapsulating the solar matrix. The leads 56 extend through the gel layer 58 for providing access to electricity created by the solar cell matrix 54. A superstrate layer 60, typically comprising glass, may be disposed on the gel layer 58 opposite the leads 56 extending through the gel layer 58. The backing layer 26 is disposed on the gel layer 58 opposite the superstrate layer 60.

Referring to FIGS. 15-17, the hole 22 is formed in the backing layer 26 for providing external access to the leads 56. The leads 56 may be spaced apart such that the hole 22 only provides access to one of the leads 56 and a second hole must be formed to provide access to the other one of the leads 56. A junction box 61 may be coupled to the solar cell laminate 28 at the location of the leads 56. The junction box 61 is in electrical communication with the leads 56 extending through the gel layer 58 for receiving an electrical current from the solar cell matrix 54.

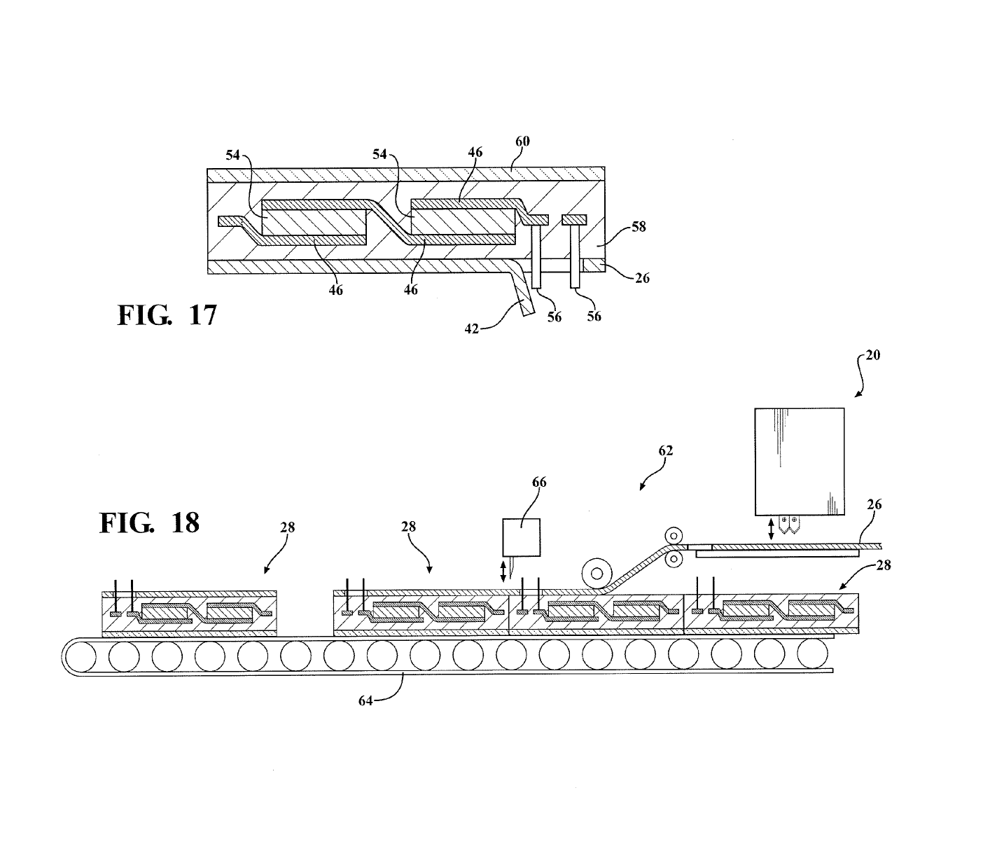

A location of the leads 56 relative to the solar cell matrix 54 depends on requirements of the end user. Different end users may have different location requirements for the leads 56. As such, the size and/or shape of the hole 22 in the backing layer 26 is dependent on the location of the leads 56. Ideally, the hole 22 formed in the backing layer 26 is as small as possible to minimize potential entry points for hazards, such as weather elements, into the solar cell laminate 28 that can damage the solar cell matrix 54 thereby preventing the solar cell matrix 54 from generating electricity. Furthermore, it is beneficial to form the hole 22 in the backing layer 26 with the flap 42, as shown in FIG. 17, such that the flap 42 can be pulled back to gain access to the leads 56 and then unfolded to cover the hole 22 in the backing layer 26 to protect the solar cell laminate 28.

The actuatable punch assembly 20, and, more specifically, the cutting device 38 can be used to pierce the backing layer 26 of the solar cell matrix 54 for forming the hole 22 in the backing layer 26 to provide access to the leads 56 extending through the solar cell laminate 28. Because a location of the leads 56 of the solar cell laminate 28 vary based on the desire of the end user, a size and/or location of the hole 22 relative to the backing layer 26 may need to be adjusted for each end user. The leads 56 may be spaced apart from one another such that more than one hole 22 needs to be formed in the backing layer 26.

As described above, the segment block 36 allow for quick adjustment of the cutting device 38 for varying the size and/or location of the hole 22. Segment blocks 36 may be added to the base plate 34 for forming another hole 22 in the backing layer 26 to accommodate leads 56 that are spaced apart such that the size of the hole 22 in the backing layer 26 becomes too large that it is undesirable to create a single hole 22 of that size in the backing layer 26.

The actuatable punch assembly 20 may be used in a method of manufacturing the solar cell laminate 28. A schematic of a continuous manufacturing apparatus 62 for producing the solar cell laminate 28 is shown in FIG. 18. However, the solar cell laminate 28 does not have to be manufactured by a continuous process. As shown in FIG. 18, a continuous belt 64 is used to advance the solar cell laminate 28 along the manufacturing apparatus 62. As shown, the hole 22 in the backing layer 26 is formed away from the solar cell matrix 54 and is subsequently placed on the gel layer 58 to form the solar cell laminate 28. A separating device 66 can be used to separate the backing layer 26 into individual pieces for coupling to the gel layer 58 of the solar cell laminate 28.

The method of manufacturing the solar cell laminate 28 includes the steps of positioning the backing layer 26 of the solar cell laminate 28 relative to the actuatable punch assembly 20, selecting the size of the hole 22 to be formed in the backing layer 26 to allow the lead 56 to be disposed through the backing layer 26, adjusting the cutting device 38 in accordance with the size of the hole 22 to be formed in the backing layer 26, forming the hole 22 in the backing layer 26 by moving the actuatable punch assembly 20 from the spaced position to the cutting position, and applying the backing layer 26 to the gel layer 58 with the leads 56 extending from the solar cell matrix 54 through the hole 22 formed in the backing layer 26 thereby forming the solar cell laminate 28.

The method of manufacturing the solar cell laminate 28 may include the step of adjusting at least one of the cutting devices 38. The method may include the step of positioning the leads 56 through the hole 22 formed in the backing layer 26. For example, the leads 56 may be pulled through the hole 22 of the backing layer 26. Alternatively, the leads 56 may be bent at the ribbon 46. The leads 56 may be a portion of the ribbon 46, which is bent to form the leads 56. Said differently, the leads 56 may be integral with the ribbon 46.

Similar to the method of forming a hole 22 in the article 24, the method of manufacturing the solar cell laminate 28 may include the steps of piercing the backing layer 26 with the cutting device 38 to form the foldable flap 42 coving the hole 22 in the backing layer 26, and folding the flap 42 back upon the backing layer 26. Folding the flap 42 back upon the backing layer 26 allows the leads 56 to be positioned through the backing layer 26.

Once the backing layer 26 is coupled to the gel layer 58 of the solar cell laminate 28 and the leads 56 are positioned through the backing layer 26, the leads 56 can be coupled to the junction box 61. The flap 42 is unfolded to cover the hole 22 once the leads 56 are positioned through the backing layer 26. The leads 56 are then coupled to the junction box 61 and the junction box 61 is coupled to the solar cell laminate 28.

The method of manufacturing the solar cell laminate 28 may further include the steps of identifying the location to form the hole 22 in the backing layer 26 and adjusting the segment block 36 relative to the base plate 34 based on the location identified to form the hole 22 in the backing layer 26. The step of adjusting the cutting device 38 may be further defined as adjusting the position of the cutting device 38 relative to the segment block 36 and/or adjusting the position of the segment block 36 relative to the base plate 34 based on the size of the hole 22 to be formed in the backing layer 26. When the actuatable punch assembly 20 includes the automated cutting device adjuster a solar cell identifier is entered into the automated cutting device adjuster to automatically adjust the position of the cutting device 38 relative to the segment block 36 and/or to automatically adjust the position of the segment block 36 relative to the base plate 34 based on the solar cell identifier.

The actuatable punch assembly 20 may be employed in a continuous method of manufacturing the solar cell laminate 28. In such a method, the backing layer 26 may be further defined as a first backing layer 26 and a second backing layer 26 and the solar cell laminate 28 may be further defined as a first solar cell laminate 28 and a second solar cell laminate 28. As such, the method of manufacturing the solar cell laminate 28 may further include the steps of positioning the second backing layer 26 relative to the actuatable punch assembly 20, selecting the size of the hole 22 to be formed in the second backing layer 26, adjusting the cutting device 38 in accordance with the size of the hole 22 to be formed in the second backing layer 26, forming the second hole 22 in the second backing layer 26 by moving the actuatable punch assembly 20 from the spaced position to the cutting position such that the cutting device 38 pierces the second backing layer 26, and applying the second backing layer 26 to a second gel layer 58 of the second solar cell laminate 28 with the leads 56 extending through the hole 22 formed in the second backing layer 26 thereby forming the second solar cell laminate 28.

The desired size or even the location of the hole 22 in the second backing layer 26 may be different than the size and or location of the hole 22 to be formed in the first backing layer 26. As such, the actuatable punch assembly 20 may include the automated cutting device adjuster and a second solar cell identifier may be entered into the automated cutting device adjuster to automatically adjust the position of the cutting device 38 relative to the segment block 36 and/or to automatically adjust the position of the segment block 36 relative to the base plate 34 based on the second solar cell identifier.

Many modifications and variations of the present invention are possible in light of the above teachings. The foregoing invention has been described in accordance with the relevant legal standards; thus, the description is exemplary rather than limiting in nature. Variations and modifications to the disclosed embodiment may become apparent to those skilled in the art and do come within the scope of the invention. Accordingly, the scope of legal protection afforded this invention may only be determined by studying the following claims.

What is claimed is:

1. A method of manufacturing a solar cell laminate using an actuatable punch assembly with the solar cell laminate comprising a solar cell matrix having at least one lead coupled to and extending from the solar cell matrix, a gel layer encapsulating the solar matrix with the lead extending through the gel layer, a superstrate layer disposed on the gel layer 58 opposite the lead extending through the gel layer, a backing layer disposed on the gel layer opposite the superstrate layer and with the actuatable punch assembly comprising an actuator operational between a cutting position and a spaced position, a base plate defining a plurality of cavities, at least one segment block coupled to the base plate; and at least one cutting device, said method comprising the steps of;
positioning the backing layer relative to the actuatable punch assembly;
selecting a size of a hole to be formed in the backing layer to allow the lead to be disposed through the backing layer;
adjusting the cutting device in accordance with the size of the hole to be formed in the backing layer;
forming the hole in the backing layer by moving the actuatable punch assembly from the spaced position to the cutting position; and
applying the backing layer to the gel layer 58 with the lead extending from the solar cell matrix through the hole formed in the backing layer thereby forming the solar cell laminate.

2. A method as set forth in claim 1 further comprising the step of positioning the lead such that the lead extends from the gel layer 58 through the hole formed in the backing layer.

3. A method as set forth in claim 1 wherein the step of forming the hole in the backing layer is further defined as piercing the backing layer with the cutting device to form a foldable flap coving the hole in the backing layer.

4. A method as set forth in claim 1 wherein the step of adjusting the cutting device is further defined as adjusting a position of the cutting device relative to the segment block and/or adjusting the position of the segment block relative to the base plate based on the size of the hole to be formed in the backing layer.

5. A method as set forth in claim 4 wherein the actuatable punch assembly further includes an automated cutting device adjuster for adjusting the position of the cutting device relative to the segment block and/or for adjusting the position of the segment block relative to the base plate based on the size of the hole to be formed in the backing layer and wherein the step of selecting the size of the hole to be formed in the backing layer is further defined as entering a solar cell identifier into the automated cutting device adjuster to automatically adjust the position of the cutting device relative to the segment block and/or to automatically adjust the position of the segment block relative to the base plate based on the solar cell identifier.

6. A method as set forth in claim 1 wherein the backing layer and the solar cell laminate are further defined as a first backing layer and a first solar cell laminate and said method further comprising the steps of:
positioning a second backing layer relative to the actuatable punch assembly;
selecting a size of a hole to be formed in the second backing layer that is different from the size of the hole formed in the first backing layer;
adjusting the cutting devices in accordance with the size of the hole to be formed in the second backing layer;
forming the second hole in the second backing layer by moving the actuatable punch assembly from the spaced position to the cutting position such that the cutting device pierces the second backing layer; and
applying the second backing layer to a second gel layer 58 of the second solar cell laminate with the lead extending through the hole formed in the second backing layer thereby forming the second solar cell laminate.

7. A method as set forth in claim 6 wherein the actuatable punch assembly further includes an automated cutting device adjuster for adjusting the position of the cutting device relative to the segment block and/or for adjusting the position of the segment block relative to the base plate based on the size of the hole to be formed in the first and second backing layers and wherein the step of selecting the size of the hole to be formed in the second backing layer is further defined as entering a second solar cell identifier into the automated cutting device adjuster to automatically adjust the position of the cutting device relative to the segment block and/or to automatically adjust the position of the segment block relative to the base plate based on the second solar cell identifier.

8. A solar cell laminate comprising:
a solar cell matrix having at least one lead coupled to and extending from said solar cell matrix;
a gel layer encapsulating said solar cell matrix with said lead extending through said gel layer;
a superstrate layer disposed on said gel layer 58 opposite said lead extending from said gel layer;
a backing layer disposed on said gel layer opposite said superstrate layer with said backing layer defining a hole at a location of the lead extending though said gel layer to allow access to said lead;
wherein said backing layer has a foldable flap moveable between an exposed position and a sealing position such that said foldable flap allows access to said hole defined by said backing layer, and therefore said lead extending through said gel layer, in said exposed position and covers the hole defined by said backing layer in said sealing position.

9. A solar cell laminate as set forth in claim 8 further comprising a junction box in electrical communication with said lead extending through said gel layer for receiving an electrical current from said solar cell matrix.

10. A solar cell laminate as set forth in claim 8 wherein said junction box is coupled to said solar cell laminate at the location of the lead extending through said gel layer.

11. An actuatable punch assembly for forming a hole within an article, said actuatable punch assembly comprising:
an actuator operational between a cutting position and a spaced position;
a base plate coupled to said actuator;
at least one segment block adjustably coupled to said base plate; and
at least one cutting device adjustably coupled to said segment block with said cutting device for forming the hole within the article;
wherein said base plate, said segment block, and said cutting device move with said actuator between said cutting position and said spaced position such that said cutting device pierces the article for forming the hole within the article in said cutting position and said cutting device is spaced from the article in said spaced position; and
wherein said segment block is adjustable relative to said base plate and with said cutting device adjustable relative to said segment block for varying a position of said cutting device relative to the article to vary a size of the hole formed in the article.

12. An actuatable punch assembly as set forth in claim 11 further comprising an automated cutting device adjuster for adjusting a position of said cutting device relative to said segment block and/or for adjusting a position of said segment block relative to said base plate to adjust the position of the cutting device relative to the article.

13. An actuatable punch assembly as set forth in claim 12 wherein said base plate defines a plurality of cavities with said segment block coupled to said base plate at one of said cavities.

14. An actuatable punch assembly as set forth in claim 11 wherein the article is further defined as a backing layer of a solar cell laminate with the solar cell laminate comprising a solar cell matrix having a lead coupled to and extending from the solar cell matrix, a gel layer encapsulating the solar matrix with the lead extending through the gel layer and the backing layer, and a superstrate layer disposed on the gel layer 58 opposite the lead extending through the gel layer, wherein said cutting device pierce the backing layer of the solar cell matrix for providing access to the lead extending through the solar cell laminate.

15. A method of forming a hole within an article using an actuatable punch assembly with the actuatable punch assembly comprising an actuator operational between a cutting position and a spaced position, a base plate defining a plurality of cavities, at least one segment block; and at least one cutting device, said method comprising the steps of;
positioning the article relative to the actuatable punch assembly;
selecting a size of the hole to be formed within the article;
adjusting the cutting devices in accordance with the size selected for the hole to be formed within the article;
adjusting the cutting device in accordance with the size of the hole to be formed in the backing layer;
forming the hole in the article by moving the actuatable punch assembly from the spaced position to the cutting position such that the cutting device pierces the article.

16. A method as set forth in claim 15 wherein the step of adjusting the cutting device is further defined as adjusting a position of the cutting device relative to the segment block and/or adjusting the position of the segment block relative to the base plate based on the size of the hole to be formed in the article.

17. A method as set forth in claim 16 wherein the actuatable punch assembly further includes an automated cutting device adjuster for adjusting the position of the cutting device relative to the segment block and/or for adjusting the position of the segment block relative to the base plate based on the size of the hole to be formed in the article and wherein the step of selecting the size of the hole to be formed in the article is further defined as entering a article identifier into the automated cutting device adjuster to automatically adjust the position of the cutting device relative to the segment block and/or to automatically adjust the position of the segment block relative to the base plate based on the article identifier.

18. A method as set forth in claim 15 wherein the article is further defined as a first article and said method further comprising the steps of:
positioning a second article relative to the actuatable punch assembly;
selecting a size of a hole to be formed in the second article that is different from the size of the hole formed in the first article;
adjusting the cutting devices in accordance with the size of the hole to be formed in the second article; and
forming the second hole in the second article by moving the actuatable punch assembly from the spaced position to the cutting position such that the cutting device pierces the second article.

19. A method as set forth in claim 18 wherein the actuatable punch assembly further includes an automated cutting device adjuster for adjusting the position of the cutting device relative to the segment block and/or for adjusting the position of the segment block relative to the base plate based on the size of the hole to be formed in the first and second articles and wherein the step of selecting the size of the hole to be formed in the second article is further defined as entering a second article identifier into the automated cutting device adjuster to automatically adjust the position of the cutting device relative to the segment block and/or to automatically adjust the position of the segment block relative to the base plate based on the second article identifier.
